(19) United States
(12) Patent Application Publication
(10) Pub. No.: US 2014/0373881 A1
(43) Pub. Date: Dec. 25, 2014

(54) SUBSTRATE TREATING APPARATUS

(71) Applicant: Samsung Electronics Co., Ltd., Suwon-Si (KR)

(72) Inventors: Jung-Min OH, Incheon (KR); Kyoungseob KIM, Suwon-si (KR); Young-Hoo KIM, Anyang-si (KR); Yongsun KO, Suwon-si (KR); Kuntack LEE, Suwon-si (KR); Yongmyung JUN, Hwaseong-si (KR); Yong-Jhin CHO, Hwaseong-si (KR)

(73) Assignee: Samsung Electronics Co., Ltd., Suwon-Si (KR)

(21) Appl. No.: 14/207,903

(22) Filed: Mar. 13, 2014

(30) Foreign Application Priority Data
Jun. 24, 2013 (KR) 10-2013-0072474

(51) Int. Cl. H01L 21/67

(52) U.S. Cl. CPC H01L 21/67051; H01L 21/67023
USPC 134/98.1; 134/198; 134/172; 134/100.1

(57) ABSTRACT

A substrate treating apparatus including a support member configured to support a substrate container configured to surround an upper portion of the support member, a nozzle member including at least one nozzle, which is configured to spray a treating solution onto the substrate disposed on the support member, and a treating solution supply unit connected to the nozzle and configured to supply the treating solution to the nozzle through a main tube may be provided.

### CROSS-REFERENCE TO RELATED APPLICATIONS

This U.S. non-provisional patent application claims priority under 35 U.S.C. §119 of Korean Patent Application No. 10-2013-0072474, filed on Jun. 24, 2013, the entire contents of which are hereby incorporated by reference.

### BACKGROUND

Some example embodiments herein relate to substrate treating apparatuses.

In general, a wafer processing process of semiconductor manufacturing processes includes, for example, a photoresist coating process, a developing and baking process, an etching process, a chemical vapor deposition process, an ashing process, etc. Further, a wet cleaning process using chemicals or deionized water (DIW) may be performed to remove various contaminants, which are attached to a surface of a substrate during performing some or each of the foregoing processes.

After the cleaning process is performed, a drying process may be performed to dry the chemicals or DIW remaining on the surface of the substrate. A substrate drying apparatus may include, for example, a spin drying apparatus for drying a semiconductor substrate by using mechanodynamical rotating force and an isopropyl alcohol (IPA) drying apparatus for drying a semiconductor substrate by using chemical reaction of IPA.

### SUMMARY

Some example embodiments provide substrate treating apparatuses configured to dry a substrate effectively.

According to one example embodiment of the inventive concepts, a substrate treating apparatuses includes a support member supporting a substrate when a process is performed, a container configured to surround an upper portion of the support member, a nozzle member including at least one nozzle configured to spray a treating solution onto the substrate disposed on the support member, and a treating solution supply unit connected to the nozzle and configured to supply the treating solution to the nozzle through a main tube.

The nozzle member may include an arm on which the nozzle is disposed, a support shaft connected to a side of the arm, and a support shaft driver configured to drive the support shaft.

The support shaft driver may be configured to elevate the support shaft such that a distance between the nozzle and the substrate is adjusted.

The support shaft driver may be configured to rotate the support shaft.

The nozzle member may include a plurality of nozzles and the nozzles may be disposed at a same horizontal distance with respect to a vertical axis extending from a center of the substrate when the arm is located above the substrate and configured to horizontally cross the vertical axis.

The arm may include a main arm having a first end portion and a second end portion, the first and second end portions being opposite to each other, the first end portion connected to the support shaft, and a branch arm branched from the second end portion of the main arm. The nozzles may be provided on the main arm and the branch arm.

When the main arm is configured to horizontally cross above the substrate and through the vertical axis extending from the center of the substrate. The branch arm may protrude from a branch area of the main arm, the branch area at the second end portion.

The nozzles may be disposed at a same distance with respect to the branch area.

The treating solution supply unit may include a deionized water tank connected to the main tube through a first connecting tube to supply deionized water, and an organic solvent tank connected to the main tube through a second connecting tube to supply an organic solvent.

A first valve may be provided in the first connecting tube and may be configured to one of open or close the first connecting tube and adjust an amount of the deionized water supplied into the first connecting tube. A second valve may be provided in the second connecting tube and may be configured to one of open or close the second connecting tube and adjust an amount of the organic solvent supplied into the second connecting tube.

The substrate treating apparatus may be configured to control the first and second valves such that the treating solution sprayed from the nozzle is changed in order of the deionized water, a mixed solution of the deionized water and the organic solvent, and the organic solvent.

A concentration of the organic solvent in the mixed solution of the deionized water and the organic solvent gradationally may increase as time elapses

A mixing space may be defined in the arm. The mixing space may be provided between the nozzle and the main tube.

The treating solution supply unit may further include a mixing tank disposed between the first connecting tube and the main tube and between the second connecting tube and the main tube.

According to another example embodiment of the inventive concepts, a substrate treating apparatus includes at least one nozzle configured to spray a treating solution onto a substrate, and a treating solution supply unit configured to selectively mix deionized water and at least one organic solvent to form the treating solution and supply the treating solution to the nozzle.

The at least one nozzle may include a plurality of nozzles, which are substantially equidistant with respect to a vertical axis extending from a center of the substrate.

The treating solution supply unit may include a deionized water tank connected to a main tube through a first connecting tube to supply the deionized water, the first connecting tube including a first valve, an organic solvent tank connected to the main tube through a second connecting tube to supply the organic solvent, the second connecting tube including a second valve, and a main tube with a mixing space defined therein.

The substrate treating apparatus may further include a mixing tank configured to temporarily accommodate at least one of the deionized water and the organic solvent between the main tube and the first and second valves.

The substrate treating apparatus may be configured to control the first and second valves such that the treating solution sprayed from the nozzle gradually changes in order of the deionized water, a mixed solution of the deionized water and the organic solvent, and the organic solvent

### BRIEF DESCRIPTION OF THE DRAWINGS

The accompanying drawings are included to provide a further understanding of the inventive concept, and are incorporated in and constitute a part of this specification. The drawings illustrate example embodiments of the inventive concepts and, together with the description, serve to explain principles of the inventive concepts. In the drawings:

FIG. 1 is a schematic cross-sectional view of a substrate treatment apparatus according to an example embodiment;

FIG. 2 is a view of a state in which a treating solution is sprayed from a nozzle member onto a top surface of a substrate;

FIG. 3 is a view of a state in which a distance between a nozzle and the substrate is adjusted;

FIG. 4 is a plan view of a substrate treating apparatus in a state where a nozzle moving part rotates;

FIG. 5 is a view illustrating an end of a nozzle member according to another example embodiment;

FIG. 6 is a plan view of a substrate treating apparatus including the nozzle member of FIG. 5;

FIG. 7 is a view illustrating an end of a nozzle member according to still another example embodiment;

FIG. 8 is a plan view of a substrate treating apparatus on which the nozzle member of FIG. 7 is disposed;

FIG. 9 is a view of a state in which an organic solvent supply unit is connected to an arm according to an example embodiment;

FIG. 10 is a view of a state in which an organic solvent supply unit is connected to a nozzle according to an example embodiment;

FIG. 11 is a flowchart illustrating an operation process of the organic solvent supply unit of FIG. 10; and

FIG. 12 is a view of a state in which an organic solvent supply unit is connected to a nozzle according to another example embodiment.

### DETAILED DESCRIPTION OF EXAMPLE EMBODIMENTS

Example embodiments of the inventive concepts will be described below in more detail with reference to the accompanying drawings, in which some example embodiments are shown. Example embodiments may, however, be embodied in many different forms and should not be constructed as limited to the example embodiments set forth herein. Rather, these example embodiments are provided so that this disclosure will be thorough and complete, and will fully convey the scope of example embodiments to those skilled in the art. In the drawings, the configurations of elements (e.g., the sizes and relative sizes of the various layers and regions) may have been exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention. It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments of the present invention will be explained in further detail with reference to the accompanying drawings.

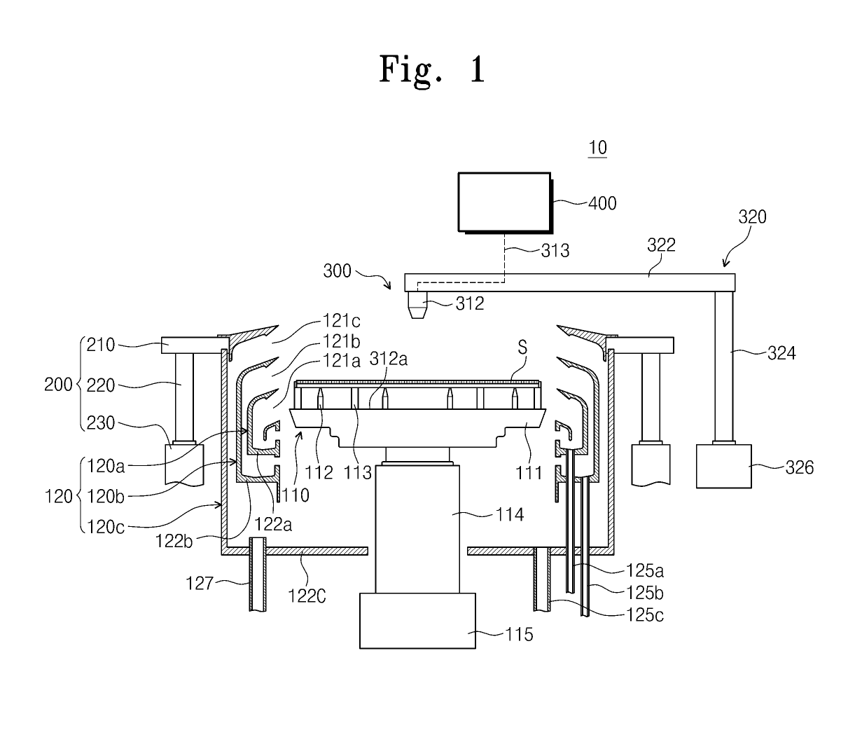

FIG. 1 is a schematic cross-sectional view of a substrate treatment apparatus according to an example embodiment.

According to this example embodiment, a substrate treating apparatus 10 includes a support member 110, a container 120, an elevation unit 200, a nozzle member 300, and a treating solution supply unit 400.

The support member 110 supports a substrate S when a process is performed. The support member 110 may include a spin head 111, a support pin 112, a chucking pin 113, a rotation shaft 114, and a rotation shaft driver 115.

The spin head 111 supports the substrate S. The spin head 111 may have a circular top surface. The top surface of the spin head may have a diameter greater than that of the substrate S. The spin head 111 may have a bottom surface having a diameter less than that of the top surface thereof. Also, the spin head 111 may have a side surface that is inclined so that the spin head 111 has a diameter gradually decreasing from the top surface to the bottom surface thereof.

The support pin 112 and the chucking pin 113 are provided on the top surface of the spin head 111. The support pin 112 protrudes upward from the top surface of the spin head 111. The substrate S is placed on an upper end of the support pin 112. The support pin 112 may be provided in plurality, and thus the plurality of support pins 112 may be disposed spaced apart from each other on the top surface of the spin head 111. For example, at least three support pins 112 may be provided at various points of a ring shape.

The chucking pin 113 protrudes upward from the top surface of the spin head 111. The chucking pin 113 supports a side portion of the substrate S. When the spin head 111 is rotated, the chucking pin 113 may prevent the substrate S from being laterally separated from the spin head 111 by centrifugal force. The chucking pin 113 may be provided in plurality, and thus the plurality of chucking pins 113 may be disposed spaced apart from each other along an edge region of the top surface of the spin head 111. For example, at least three chucking pins 113 may be provided at various points of a ring shape. The chucking pin 113 may be disposed far away from a center of the spin head 111. The chucking pin 113 may move along a radial direction of the spin head 111. When the substrate S is loaded or unloaded, the chucking pin 113 may move along the radial direction of the spin head 111 so that the chucking pin 113 is spaced apart from or contacts a side surface of the substrate S.

The rotation shaft 114 is disposed under the spin head 111 to support the spin head 111. The rotation shaft 114 may be provided as a hollow shaft. The rotation shaft 114 transmits rotation force generated by the rotation shaft driver 115 to the spin head 111. The rotation shaft driver 115 is disposed on a lower end of the rotation shaft 114. The rotation shaft driver 115 generates the rotation force for rotating the rotation shaft 114.

The container 120 may prevent a treating solution used in the process and/or fume generated when the process is performed from being spattered or spilled to the outside. The container 120 defines a space in which the substrate S is treated. The container 120 has an opened upper side. The container 120 is provided to surround an upper portion of the support member 110.

According to this example embodiment, the container 120 includes a plurality of collecting boxes 120a, 120b, and 120c, which separates and recovers the treating solution used in the process. The collecting boxes 120a, 120b, and 120c collect different treating solutions from the treating solutions used for the processes, respectively. In the example embodiment, the container 120 includes an internal collecting box 120a, an intermediate collecting box 120b, and an external collecting box 120c. However, the number of collecting boxes 120a, 120b, and 120c of the container 120 may be different according to the number of treating solution to be separated and collected or design requirements.

The internal collecting box 120a is disposed to surround the spin head 111, the intermediate collecting box 120b is disposed to surround the internal collecting box 120a, and the external collecting box 120c is disposed to surround the intermediate collecting box 120b.

The collecting boxes 120a, 120b, and 120c have inflow holes 121a, 121b, and 121c that communicate with spaces within the container 120, respectively. Each of the inflow holes 121a, 121b, and 121c may be provided in a ring shape around the spin head 111. The treating solutions provided for the substrate treatment are scattered by the rotation force of the substrate S and then are introduced into the collecting boxes 120a, 120b, and 120c through the inflow holes 121a, 121b, and 121c, respectively. The inflow hole 121c of the external collecting box 120c may be disposed above an inflow hole 121b of the intermediate collecting box 120b, and the inflow hole 121b of the intermediate collecting box 120b may be disposed above the inflow hole 121a of the internal collecting box 120a. Thus, for example, the inflow holes 121a, 121b, and 121c of the internal collecting box 120a, the intermediate collecting box 120b, and the external collecting box 120c may be disposed at heights different from each other. Discharge tubes 125a, 125b, and 125c are connected to bottom walls 122a, and 122b, and 122c of the collecting boxes 120a, 120b, and 120c, respectively. The treating solutions introduced into the collecting boxes 120a, 120b, and 120c are separated and collected through the discharge tubes 125a, 125b, and 125c, respectively. Also, an exhaust tube 127 may be connected to the bottom wall 122c of the external collecting box 120c. The exhaust tube 127 exhausts a gas or fume that is generated from the treating solutions introduced into the collecting boxes 120a, 120b, and 120c to the outside.

The elevation unit 200 vertically moves the container 120 to adjust a relative height of the container 120 with respect to the spin head 111. The elevation unit 200 includes a bracket 210, a moving shaft 220, and a driver 230. The bracket 210 is affixed to an outer wall of the container 120. The moving shaft 220 is coupled to the bracket 210 and the driver 230 vertically moves the driver. When the substrate S is loaded on or unloaded from the spin head 111, the elevation unit 200 may allow the container 120 to descend so as to allow the spin head 111 to protrude upward from the container 120. Also, when the process is performed, the elevation unit 200 may adjust a height of the container 120 to introduce each of the different treating solutions supplied onto the substrate S into one of the collecting boxes 120a, 120b, and 120c.

According to another example embodiment, the elevation unit 200 may vertically move the spin head 111.

The nozzle member 300 sprays a treating solution onto the top surface of the substrate. The treating solution sprayed from the nozzle member 300 may be, e.g., an organic solvent, DIW, or a mixed solution of the organic solvent and the DIW. The nozzle member 300 includes a nozzle 312 and a nozzle moving part 320.

The nozzle 312 may supply the organic solvent onto the top surface of the substrate S. The substrate S on which the organic solvent is supplied may have a top surface on which the DIW has been applied. For example, a processing process and a rinse process may be sequentially performed onto the substrate S. The processing process may include, e.g., a developing process, an etching process, an ashing process, or a cleaning process. A chemical solution used in the processing process may include, e.g., a developing solution, sulfuric acid, nitric acid, ammonia, hydrofluoric acid, or a mixed solution of the above-described chemical solution and deionized water. When the processing process is completed, the rinse process may be performed. The rinse process may be performed by supplying the DIW onto the top surface of the substrate S. The DIW may remove the chemical solution used in the processing process from the substrate S. Also, the DIW may remove reaction byproducts or particles generated due to the chemical solution from the substrate S during the rinse process.

The nozzle moving part 320 may move the nozzle 312 to uniformly supply the fluid (e.g., treating solutions) sprayed from the nozzle member 300 from a central region to an edge region of the substrate S. The nozzle moving part 320 includes an arm 322, a support shaft 324, and a support shaft driver 326. The nozzle 312 is provided on the arm 322. The support shaft 324 is connected to a side of the arm 322 to support the arm 322. The support shaft 324 is connected to the support shaft driver 326. A support shaft driver 326 supplies driving force for moving the nozzle member 300.

The treating solution supply unit 400 is connected to the nozzle 312 through a tube 313. The treating solution supply unit 400 may supply the treating solution into the nozzle 312.

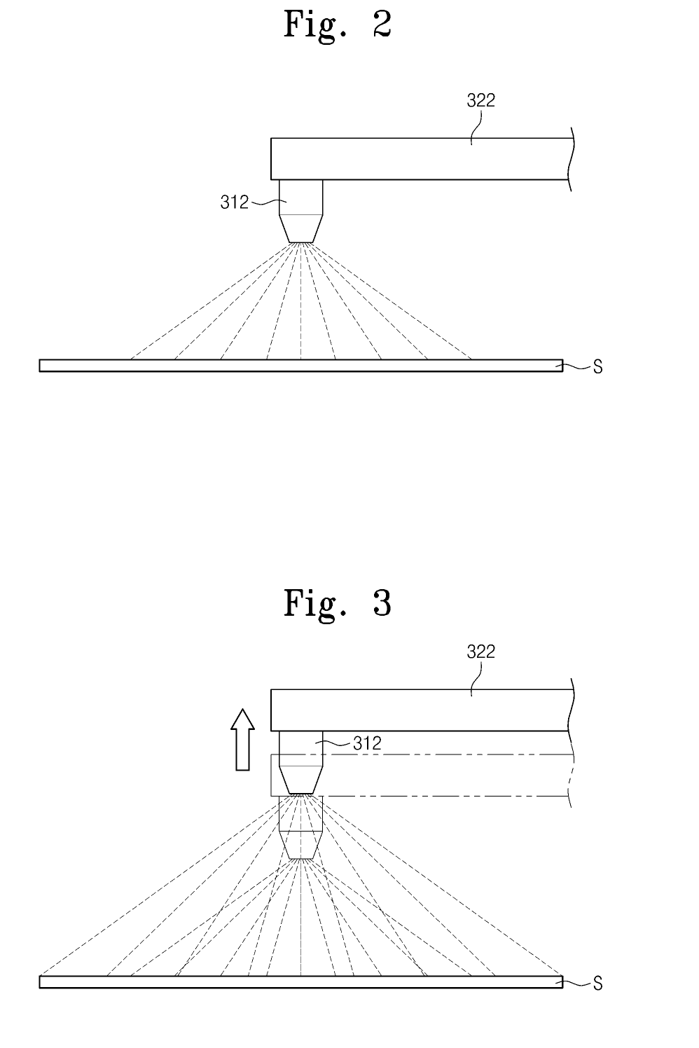

FIG. 2 is a view of a state in which the treating solution is sprayed onto the top surface of the substrate from the nozzle member.

Referring to FIGS. 1 and 2, the nozzle 312 is configured to spray the organic solvent or the mixed solution of the organic solvent and the DIW onto the top surface of the substrate S using a spraying method.

The organic solvent may include isopropyl alcohol (IPA). The IPA dries the substrate S by using volatility. For example, the IPA may substitute the DIW, which is applied to the surface of the substrate S during the processing process and remains on the substrate S after the rinse process, such that moisture from the surface of the substrate S is removed. The DIW has a surface tension greater than that of the organic solvent. Thus, if a region of the substrate S in which the organic solvent is not supplied occurs, a deviation between the surface tensions of a region of the substrate S in which the organic solvent is supplied and the region of the substrate S in which the organic solvent is not supplied may occur. Also, if an amount of organic solvent supplied into each of regions of the substrate S is not uniform, a ratio between the DIW and the organic solvent may be different according to the regions of the substrate S, and thus a deviation in surface tension may occur. The deviation in surface tension generates force on the top surface of the substrate S, and thus may damage the surface of the substrate S. For example, the deviation in surface tension may collapse a pattern formed on the top surface of the substrate S.

Because the organic solvent is sprayed using the spraying method, the organic solvent having a small particle size may be supplied onto the substrate S. Thus, the region of the substrate S in which the organic solvent is not applied may be lessened and a uniform amount of the organic solvent may be applied at desired (or, alternatively predetermined) regions of the substrate S. Thus, the deviation in surface tension on the top surface of the substrate S may be reduced, thereby reducing or preventing the substrate S from being damaged.

FIG. 3 is a view of a state in which a distance between the nozzle and the substrate is adjusted.

Referring to FIGS. 1 and 3, a distance between the nozzle 312 and the substrate S may be varied. For example, the support shaft driver 326 may elevate the support shaft 324 and the arm 322. When a distance between the nozzle 312 and the top surface of the substrate S is relatively short, the region of the substrate S in which the organic solvent is not applied may occur. Further because a pressure of the organic solvent sprayed from the nozzle 312 may be adjusted. When the organic solvent is sprayed in a relatively high pressure, the substrate S may be damaged by collision between the organic solvent and the substrate S. Depending on the pressure at which the organic solvent is sprayed, an area on which the organic solvent is spread in the radial direction of the substrate S may be different. Thus, the region of the substrate S on which the organic solvent is not applied may occur, for example, in the edge region of the substrate S.

When the distance between the nozzle 312 and the substrate S increases, a distance in which the organic solvent sprayed from the nozzle 312 moves in the radial direction of the substrate S may increase. The support shaft driver 326 may adjust a height of the nozzle 312 to spray the organic solvent onto the entire top surface of the substrate S. As a result, a region or regions of the substrate S on which the organic solvent is not supplied may be minimized or prevented.

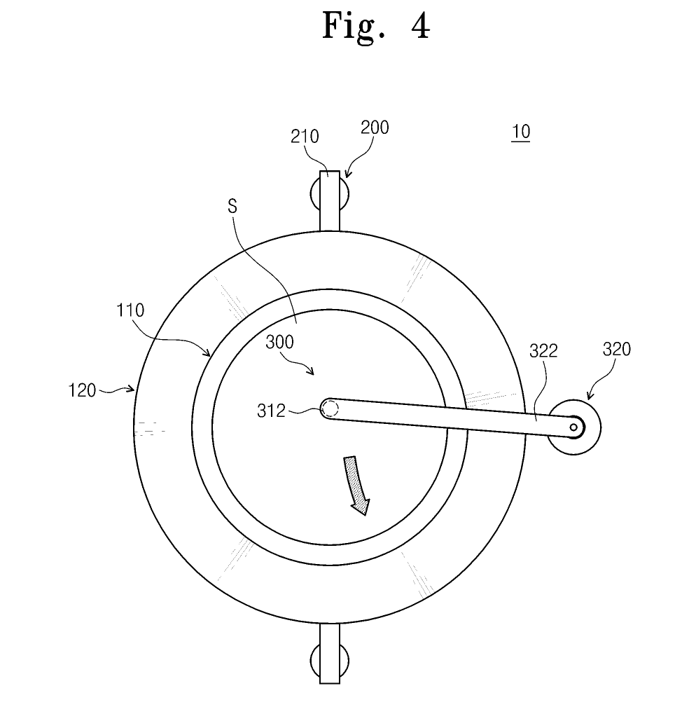

FIG. 4 is a plan view of the substrate treating apparatus in a state where the nozzle moving part rotates.

Referring to FIGS. 1 and 4, the nozzle moving part 320 is rotatably provided.

The support shaft driver 326 may rotate the nozzle moving part 320. For example, the support shaft driver 326 may rotate the support shaft 324. When the support shaft 324 rotates, the nozzle 312 may also circularly moves around the support shaft 324. The support shaft driver 326 may rotate the support shaft 324 within a range in which the nozzle 312 is located above the substrate S. Also, the support shaft driver 326 may repeatedly rotate the support shaft 324 in different directions to move the nozzle 312 in a reciprocated manner at least two times.

When the organic solvent is sprayed from the nozzle 312, an amount of the organic solvent applied on the substrate S may be different according to the distance between the nozzle 312 and the substrate S. For example, an amount of the organic solvent applied to the substrate S may be gradually decreased outward from a center of the top surface of the substrate S. When a deviation in the amount of the organic solvent applied to each region of the substrate S increases, damage to the substrate S due to the deviation in surface tension may occur or increase. When the nozzle 312 moves upward with respect to the substrate S, the deviation in amount of the organic solvent applied for each region of the substrate S may decrease, thereby reducing or preventing the top surface of the substrate S from being damaged.

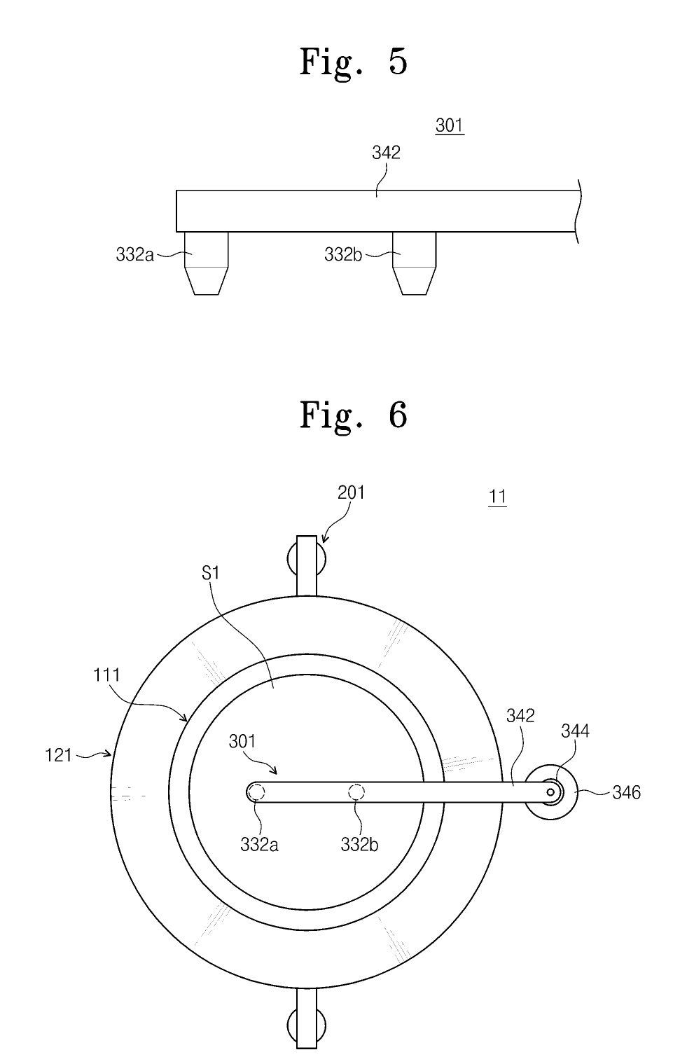

FIG. 5 is a view illustrating an end of the nozzle member according to another example embodiment. FIG. 6 is a plan view of a substrate treating apparatus including the nozzle member of FIG. 5.

In a nozzle member 301, a support shaft 344 and a support shaft driver 346 have the same or similar constitution as those of the nozzle member 300 described with reference to FIG. 1 except for a nozzle 332 (i.e., 332a and 332b) and an arm 342. Further, in a substrate treating apparatus 11, a support member 111, a container 121, and an elevation unit 201 have the same or similar constitution as those of the substrate treating apparatus 10 described with reference to FIG. 1 except for the nozzle member 301. Thus, descriptions with respect to the constitutions same or similar to those illustrated with reference to FIG. 1 will be omitted.

Referring to FIGS. 5 and 6, at least two nozzles 332a and 332b are provided on an arm 342 of the nozzle member 301. First and second nozzles 332a and 332b may be symmetrically disposed with respect to a center of a substrate S1. For example, when the arm 342 is located to pass above the center of the substrate S1, a distance between the first nozzle 332a and the center of the substrate S1 and a distance of between the second nozzle 332b and the center of the substrate S1 may be same. Thus, the first and the second nozzles 332a and 332b may spray an organic solvent in regions opposite to each other with respect to the center of the substrate S1. Therefore, the nozzle member 301 may uniformly spray the organic solvent onto a top surface of the substrate S1.

Further, in the nozzle member 301, the distance between the nozzle 332 and the substrate S1 may vary in the same manner as described with reference to FIG. 3. Further, the arm 342 may rotate in the same manner as described with reference to FIG. 4. Thus, detailed descriptions of these movements will be omitted.

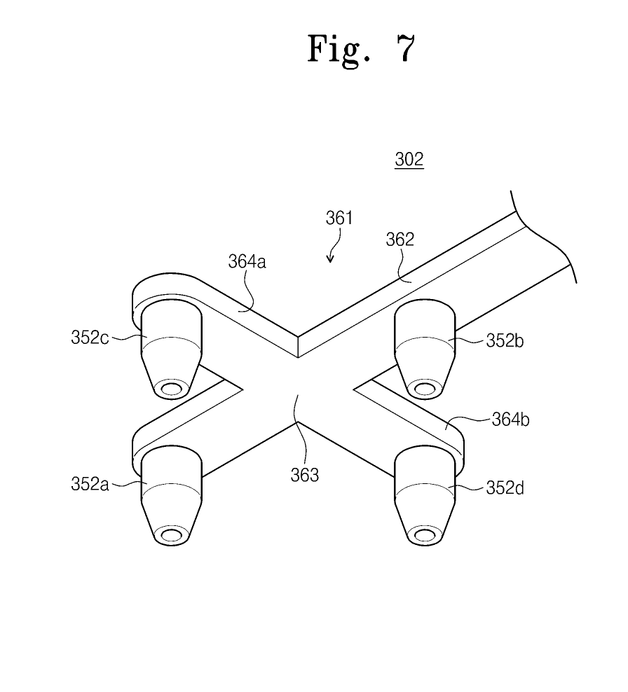

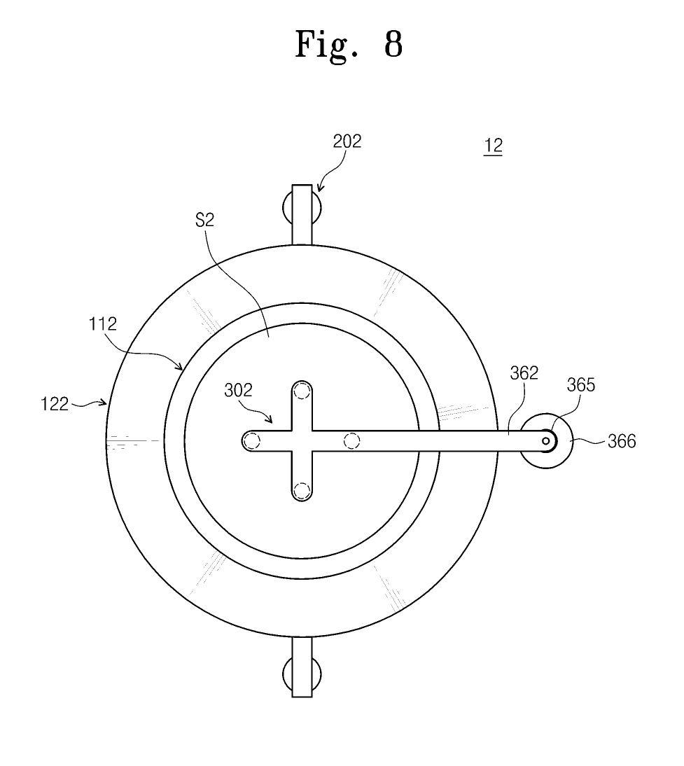

FIG. 7 is a view illustrating an end of a nozzle member according to still another example embodiment. FIG. 8 is a plan view of the substrate treating apparatus on which the nozzle member of FIG. 7 is disposed.

In a nozzle member 302, a support shaft 365 and a support shaft driver 366 have the same or similar constitution as those of the nozzle member 300 described with reference to FIG. 1 except for nozzles 352 (i.e., 352a, 352b, 352c, and 352d) and an arm 361. Further, in a substrate treating apparatus 12, a support member 112, a container 122, and an elevation unit 202 have the same or similar constitution as those of the substrate treating apparatus 10 described with reference to FIG. 1 except for the nozzle member 302. Thus, descriptions with respect to the constitutions same or similar to those illustrated with reference to FIG. 1 will be omitted.

Referring to FIGS. 7 and 8, the arm 361 includes a main arm 362 and branch arms 364 (i.e., 364a and 364b). The main arm 362 has one end portion connected to the support shaft 365. The main arm 362 has the other end portion from which the branch arms 364 are branched. The other end portion of the main arm 262 is opposite to the one end portion of the main arm 362. The branch arms 364 protrude from a branch area 363 of the main arm 362. When the main arm 362 is arranged above the substrate S2 to pass or horizontally cross a vertical axis extending from a center of the substrate S2, the branch area 363 may coincide with the vertical axis extending from the center of the substrate S2. The branch arms 364 may have bottom surfaces having the same height as that of a bottom surface of the main arm 362. Thus, a distance between the bottom surfaces of the branch arms 364 and a top surface of the substrate S2 and a distance between the bottom surface of the main arm 362 and the top surface of the substrate S2 may be the same. The branch arms 364 may be provided in plurality. For example, first and second branch arms 364a and 364b may be branched to both sides of the main arm 362, respectively, at the branch area 363.

The nozzles 352 are disposed on the main arm 362 and the branch arm 364. For example, when at least two branch arms 364 are provided, first and second nozzles 352a and 352b are disposed on the main arm 362, and third and fourth nozzles 352c and 352d are disposed on the branch arms 364. The first nozzle 352a and the second nozzle 352b may be symmetrically disposed to each other with respect the branch area 363. The third nozzle 352c and the forth nozzle 352d may be symmetrically disposed to each other with respect the branch area 363. Further, the first to fourth nozzles 352a to 352d may be disposed at a same horizontal distance with respect to the branch area 363. The horizontal distance between the branch area 363 and each of the nozzles 352a to 352d may correspond to a half of the radius of the substrate S2. Thus, each of the nozzles 352 may uniformly spray an organic solvent onto each of regions partitioned with respect to the center of the substrate S2.

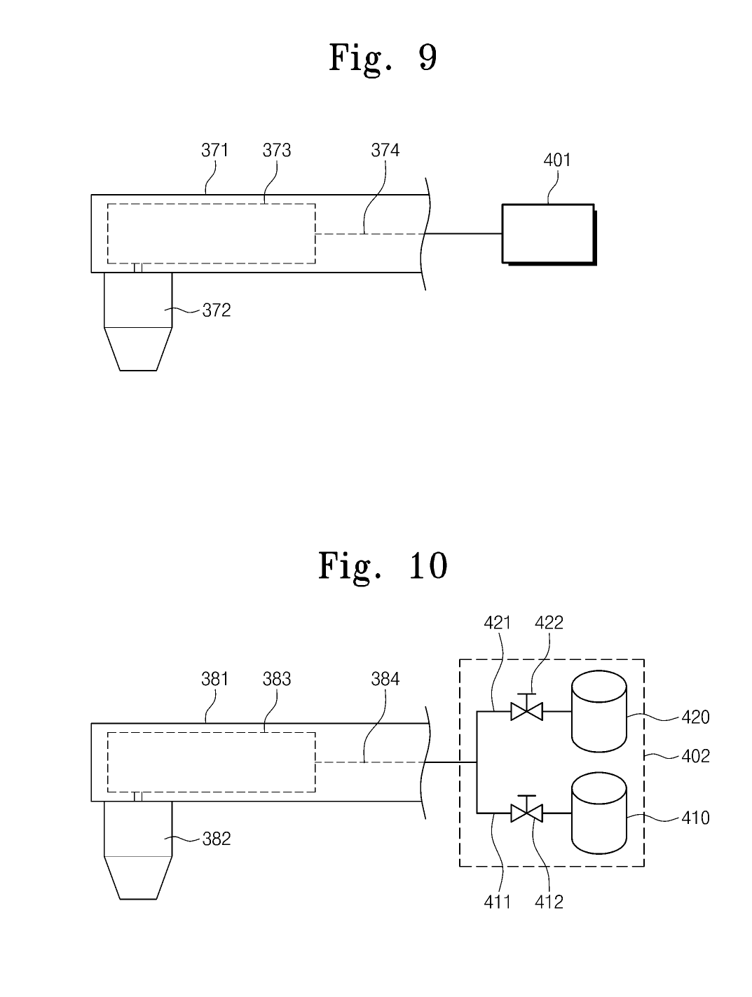

FIG. 9 is a view of a state in which an organic solvent supply unit is connected to an arm according to an example embodiment.

Referring to FIG. 9, a mixing space 373 is defined in an arm 371. The mixing space 373 is defined adjacent to a nozzle 372. The mixing space 373 is defined in a tube 374 connecting an organic solvent supply unit 401 to the nozzle 372. When the nozzle 372 is provided in plurality as shown in FIGS. 5 to 8, a single mixing space 373 may be defined such that the mixing space 373 is connected to each of the nozzles 372. Further, when the nozzle 372 is provided in plurality as shown in FIGS. 5 to 8, the mixing space 373 may be provided in plurality, for example, the number of the mixing spaces 373 may be the same as the number of the nozzles 372. For example, the mixing spaces 373 may be connected to the nozzles 372 in a one-to-one correspondence. The mixing space 373 provides a space for temporarily storing an organic solvent supplied from the organic solvent supply unit 401. Thus, an amount of organic solvent supplied into the nozzle 372 may be uniformly maintained as a time elapses.

FIG. 10 is a view of a state in which an organic solvent supply unit is connected to a nozzle according to an example embodiment. Descriptions with respect to the constitutions same or similar to those illustrated with reference to FIG. 9 will be omitted.

Referring to FIG. 10, an organic solvent supply unit 402 includes a deionized water tank 410, and an organic solvent tank 420.

The deionized water tank 410 is connected to a tube 384 through a first connecting tube 411. A first valve 412 may be provided in the first connecting tube 411. The first valve 412 may open or close the first connecting tube 411. Further, the first valve 412 may adjust an amount of deionized water supplied through the first connecting tube 411. The organic solvent tank 420 is connected to the tube 384 through a second connecting tube 421. A second valve 422 may be provided in the second connecting tube 421. The second valve 422 may open or close the second connecting tube 421. Further, the second valve 422 may adjust an amount of organic solvent supplied through the second connecting tube 421.

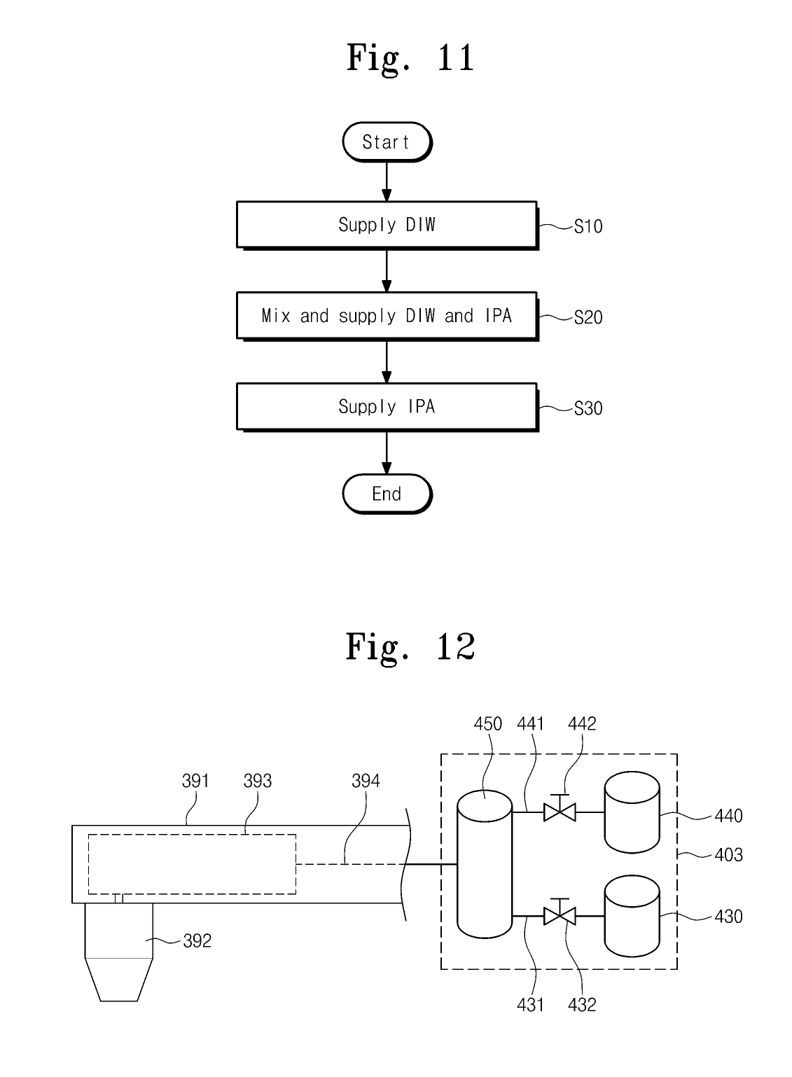

FIG. 11 is a flowchart illustrating an operation process of the organic solvent supply unit of FIG. 10.

Referring to FIGS. 10 and 11, the organic solvent supply unit 402 may sequentially supply the deionized water and the organic solvent.

First, a deionized water supply process is performed (S10). In the deionized water supply process, the organic solvent supply unit 402 supplies the deionized water onto a substrate. For example, the first valve 412 may be opened to supply the deionized water stored in the deionized water tank 410 into a nozzle 382. During this process, the second valve 422 may remain closed so that the organic solvent stored in the organic solvent tank 420 is not supplied into the nozzle 382.

After a processing process is performed, the substrate may be in a contaminated state in which a rinse process is not performed. The processing process may include, e.g., a developing process, an etching process, an ashing process, or a cleaning process. A chemical solution used in the processing process may include, e.g., a developing solution, sulfuric acid, nitric acid, ammonia, hydrofluoric acid, or a mixed solution of the above-described chemical solution and the deionized water. The chemical solution used in the processing process and reaction byproducts or particles generated during the processing process may remain on the substrate. The deionized water supplied from the nozzle 382 onto the substrate may be used to perform the rinse process. When the deionized water starts to be supplied from the nozzle 382, the substrate S2 may have undergone the processing process and a first rinse process. Then, the deionized water supplied from a nozzle 382 may be used to perform a second rinse process.

The deionized water is supplied onto the substrate for a desired (or, alternatively preset or predetermined) time, and then a mixed solution supply process is performed (S20). For example, in the mixed solution supply process, the first valve 412 and the second valve 422 are opened to supply the deionized water and the organic solvent into a tube 384. For example, when the mixed solution supply process starts, the second valve 422 is opened to supply a small amount of organic solvent into the tube 384. At this point, the first valve 412 may be controlled to reduce or adjust an amount of the deionized water supplied from the deionized water tank 410 in correspondence with the amount of the organic solvent supplied from the organic solvent tank 420. As a time elapses, a degree of an opening of the second valve 422 in the mixed solution supply process may gradationally or linearly increase. Thus, the amount of the organic solvent supplied from the organic solvent tank 420 into the tube 384 may increases as a time elapses. A degree of an opening of the first valve 412 may gradationally or linearly decrease in correspondence with the degree of opening of the second valve 422. In the mixed solution supply process, a concentration of the organic solvent supplied into the tube 384 may increase gradationally or linearly as a time elapses.

The organic solvent and the deionized water supplied into the tube 384 may be mixed with each other while flowing. When the tube 384 connecting the organic solvent supply unit 402 to the nozzle 382 increases in length, the organic solvent and the deionized water may be sufficiently mixed with each other. However, the amounts of the organic solvent and deionized water accommodated in the tube 384 increases according to the length of the tube 384. When the mixed solution of the organic solvent and deionized water accommodated in the tube 384 for a desired (or, alternatively predetermined) time or more is used to treat the substrate, quality of the treated substrate may deteriorate. However, according to example embodiments, the organic solvent and the deionized water may be further mixed in a mixing space 383. For example, the mixing space 383 may have a sectional area greater than that of the tube 384. Thus, when the organic solvent and the deionized water changes flow rates in the first and second connection tubes 411 and 422, the organic solvent and the deionized water may be first mixed in the tube 384, then further mixed in the mixing space 383, and supplied into the nozzle 382.

Thereafter, an organic solvent supply process is performed (S20). The mixed solution supply process proceeds to the organic solvent supply process reaches when the amount of the deionized water supplied into the nozzle 382 decreases, the first valve 412 is closed, and only the second valve 422 is maintained in the opened state. Thus, only the organic solvent is supplied into the nozzle 382. The organic solvent supply process may be maintained for a desired (or, alternatively preset) time until the amount of deionized water remaining on a top surface of the substrate is minimized or removed.

According to some example embodiments of the inventive concepts, a liquid applied on the top surfaces of the substrate may be gradually changed from the deionized water to the organic solvent. Thus, a change in surface tension occurring in the process in which the liquid applied on the top surfaces of the substrate is changed from the deionized water to the organic solvent may be minimized. Further, according to example embodiments of the inventive concepts, the mixed solution of the deionized water and organic solvent may be sprayed onto the entire top surfaces of the substrate as in a spraying method. Thus, differences in surface tension between regions of the substrate may be reduced or prevented, thereby reducing or preventing damage on the substrate.

FIG. 12 is a view of a state in which an organic solvent supply unit is connected to a nozzle according to another example embodiment.

Referring to FIG. 12, an organic solvent supply unit 403 includes a deionized water tank 430, an organic solvent tank 440, and a mixing tank 450.

The deionized water tank 430 is connected to the mixing tank 450 through a first connecting tube 431. A first valve 432 may be provided in the first connecting tube 432. The first valve 432 may open or close the first connecting tube 431. Further, the first valve 432 may adjust an amount of deionized water supplied through the first connecting tube 431. The organic solvent tank 440 is connected to the mixing tank 450 through a second connecting tube 441. A second valve 442 may be provided in the second connecting tube 442. The second valve 442 may open or close the second connecting tube 441. Further, the second valve 442 may adjust an amount of organic solvent supplied through the second connecting tube 441.

The mixing tank 450 may temporarily accommodate the deionized water supplied from the deionized water tank 430 and/or the organic solvent supplied from the organic solvent tank 440. Further, the mixing tank 450 mixes the deionized water supplied from the deionized water tank 430 with the organic solvent supplied from the organic solvent tank 440 to supply the resultant mixture into a tube 394.

An arm 391, a mixing space 393, and a nozzle 392 have the same or similar constitutions as those of FIG. 10 except for an organic solvent supply unit 403. For example, the arm 391, the mixing space 393, the tube 394, and the organic solvent supply unit 403 may from a treating solution supply unit. The organic solvent supply unit 403 may operate in the same or similar operation process as described with reference to FIG. 11. Thus, descriptions with regard to the operation of the organic solvent supply unit 403 will be omitted.

According to example embodiments of the inventive concepts, the substrate may be effectively dried.

The foregoing detailed descriptions may be merely an example of the inventive concept. Although some example embodiments of the inventive concepts have been described, example embodiments may be embodied in different combinations thereof, forms, and environments. It may be appreciated by those of ordinary skill in the art that various changes in forms and details may be made within the scope of example embodiments of the inventive concepts defined by the following claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A substrate treating apparatus comprising:
a support member configured to support a substrate;
a container configured to surround an upper portion of the support member;
a nozzle member including at least one nozzle, the nozzle configured to spray a treating solution onto the substrate disposed on the support member; and
a treating solution supply unit connected to the nozzle, the treating solution supply unit configured to supply the treating solution to the nozzle through a main tube.

2. The substrate treating apparatus of claim 1, wherein the nozzle member further comprises:
an arm on which the nozzle is disposed;
a support shaft connected to a side of the arm; and
a support shaft driver configured to drive the support shaft.

3. The substrate treating apparatus of claim 2, wherein the support shaft driver is configured to elevate the support shaft such that a distance between the nozzle and the substrate is adjusted.

4. The substrate treating apparatus of claim 2, wherein the support shaft driver is configured to rotate the support shaft.

5. The substrate treating apparatus of claim 2, wherein the nozzle member includes a plurality of nozzles.

6. The substrate treating apparatus of claim 5, wherein the nozzles are disposed at a same horizontal distance with respect to a vertical axis extending from a center of the substrate when the arm is located above the substrate and configured to horizontally cross the vertical axis.

7. The substrate treating apparatus of claim 5, wherein the arm comprises:
a main arm having a first end portion and a second end portion, the first and second end portions being opposite to each other, the first end portion connected to the support shaft; and
a branch arm branched from the second end portion of the main arm,
wherein the nozzles are on the main arm and the branch arm.

8. The substrate treating apparatus of claim 7, wherein, when the main arm is configured to horizontally cross above the substrate and through the vertical axis extending from the center of the substrate, and the branch arm protrudes from a branch area of the main arm, the branch area at the second end portion.

9. The substrate treating apparatus of claim 8, wherein the nozzles are disposed at a same distance with respect to the branch area.

10. The substrate treating apparatus of claim 1, wherein the treating solution supply unit comprises:
a deionized water tank connected to the main tube through a first connecting tube to supply deionized water; and
an organic solvent tank connected to the main tube through a second connecting tube to supply an organic solvent.

11. The substrate treating apparatus of claim 10, wherein a first valve is provided in the first connecting tube, the first valve configured to one of open or close the first connecting tube and adjust an amount of the deionized water supplied into the first connecting tube, and
a second valve is provided in the second connecting tube, the second valve configured to one of open or close the second connecting tube and adjust an amount of the organic solvent supplied into the second connecting tube.

12. The substrate treating apparatus of claim 11, wherein the substrate treating apparatus is configured to control the first and second valves such that the treating solution sprayed from the nozzle is changed in order of the deionized water, a mixed solution of the deionized water and the organic solvent, and the organic solvent.

13. The substrate treating apparatus of claim 12, wherein a concentration of the organic solvent in the mixed solution of the deionized water and the organic solvent gradationally increases as time elapses

14. The substrate treating apparatus of claim 10, wherein a mixing space is defined in the arm, the mixing space provided between the nozzle and the main tube.

15. The substrate treating apparatus of claim 10, wherein the treating solution supply unit further comprises:
a mixing tank disposed between the first connecting tube and the main tube and between the second connecting tube and the main tube.

16. A substrate treating apparatus comprising:
at least one nozzle configured to spray a treating solution onto a substrate; and
a treating solution supply unit configured to selectively mix deionized water and at least one organic solvent to form the treating solution and supply the treating solution to the nozzle.

17. The substrate treating apparatus of claim 16, wherein the at least one nozzle includes a plurality of nozzles, the nozzles substantially equidistant with respect to a vertical axis extending from a center of the substrate.

18. The substrate treating apparatus of claim 16, wherein the treating solution supply unit comprises:
a deionized water tank connected to a main tube through a first connecting tube to supply the deionized water, the first connecting tube including a first valve;
an organic solvent tank connected to the main tube through a second connecting tube to supply the organic solvent, the second connecting tube including a second valve; and
a main tube with a mixing space defined therein.

19. The substrate treating apparatus of claim 18, further comprising:
a mixing tank configured to temporarily accommodate at least one of the deionized water and the organic solvent between the main tube and the first and second valves.

20. A substrate treating apparatus of claim 18, wherein the substrate treating apparatus is configured to control the first and second valves such that the treating solution sprayed from the nozzle gradually changes in order of the deionized water, a mixed solution of the deionized water and the organic solvent, and the organic solvent.
